(19) United States
(12) Patent Application Publication
(10) Pub. No.: US 2024/0213678 A1
(43) Pub. Date: Jun. 27, 2024

(54) 3-D Integrated Circuit Antenna Arrays

(71) Applicant: pSemi Corporation, San Diego, CA (US)

(72) Inventors: Peter Bacon, Derry, NH (US); Sinan Goktepeli, Austin, TX (US); Kouassi Sebastien Kouassi, San Diego, CA (US)

(21) Appl. No.: 18/088,444

(22) Filed: Dec. 23, 2022

(51) Int. Cl. H01Q 9/04; H01Q 1/22; H01Q 21/06

(52) U.S. Cl. CPC H01Q 9/0407; H01Q 1/2283; H01Q 21/065

(57) ABSTRACT

Antenna structures that can be located in close proximity with respect to an associated RFFE IC regardless of antenna element size. An antenna structure, including a grid or planar antenna or an array of antenna elements, is co-fabricated as part of or with one or more associated RFFE ICs using 3-D stacking of IC dies, either directly or as part of an embedded die packaging technology. Some embodiments include a combinable co-fabricated antenna element, including at least one internally co-fabricated RF antenna element configured to be electrically connectable to a corresponding RF antenna element in a second combinable co-fabricated antenna element by means of 3-D integrated circuit stacking. Some embodiments include a plurality of combinable co-fabricated antenna elements coupled together by means of 3-D integrated circuit stacking such that the antenna elements form a grid antenna or comprise an array of antenna patches.

### BACKGROUND

### (1) Technical Field

This invention relates to electronic circuits, and more particularly to radio frequency integrated circuits and related methods.

### (2) Background

Many modern electronic systems include radio frequency (RF) transceivers; examples include cellular telephones, personal computers, tablet computers, wireless network components, televisions, cable system “set-top” boxes, automobile communication systems, wireless sensing devices, and radar systems. Many RF transceivers are capable of transmitting and receiving in full-duplex or half-duplex modes across multiple frequencies in multiple bands; for instance, in the United States, the 2.4 GHz band is divided into 14 channels spaced about 5 MHz apart, and each channel is operated in a half-duplex, time division duplex mode. As another example, a modern “smart telephone” may include RF transceiver circuitry capable of concurrently operating on different cellular communications systems (e.g., GSM, CDMA, LTE, and 5G in multiple bands within the 400-7000 MHz range), on different wireless network frequencies and protocols (e.g., various IEEE 802.11 “WiFi” protocols at 2.4 GHz, 5 GHZ, and 6 GHz), and on “personal” area networks (e.g., Bluetooth based systems).

A frequency division duplex radio system operates in one RF band for uplink RF signals (e.g., handset to base station) and a separate RF band for downlink RF signals (e.g., base station to handset). A time division duplex radio system operates in a single RF band and frequently switches between uplink and downlink RF signals in the single band. An RF band typically spans a range of frequencies (e.g., 10 to 1000 MHz per band), and actual signal transmission and reception may be in sub-bands or channels of such bands, which may overlap. Alternatively, two widely spaced RF bands may be used for signal transmission and reception, respectively.

More advanced radio systems, such as some cellular telephone systems, may be operable over multiple RF bands for signal transmission and reception. Such multi-band operation allows a single radio system to be interoperable with different international frequency allocations and signal coding systems (e.g., 5G, LTE, CDMA, GSM).

Some advanced radio systems use multiple-input, multiple-output (MIMO) technology to multiply the capacity of a radio link by using multiple transmission and receiving antennas to exploit multipath propagation. The same MIMO architecture may be used to improve the signal-to-noise ratio (SNR) of a radio link rather than its capacity. Some advanced radio systems use a phased-array antenna architecture having multiple antenna elements that enable beam steering to improve transmission range through increased antenna directivity, for example.

To accommodate multiple frequencies and multiple protocols (particularly MIMO) as well as beam-steering, a system component (e.g., a user's cell phone, sometimes known as “User Equipment” or UE) may include multiple antennas. For example, FIG. 1 is a block diagram of a prior art RF front end (RFFE) 100 in a single transmitter, four-receiver configuration. In the illustrated example, a multi-way switch 102 is coupled to multiple antennas (four, in this example) ANTI-ANT4, to a power amplifier PA, and to multiple low-noise amplifiers (four, in this example) LNA1-LNA4. The multi-way switch 102 is configured to allow connection of any amplifier (PA or LNA) to any antenna ANTI-ANT4, thus allowing both transmission of RF signals and reception of RF signals. In some embodiments, the multi-way switch 102 may include circuitry that functions to separate transmitted and received signals, such as duplexers.

Prior art RF systems operating in the low GHz range fabricate one or more antenna elements in a planar array off-die with respect to integrated circuit (IC) dies that embody an RFFE. It is common to co-locate each RFFE IC near one or more antenna elements by stacking the RFFE ICs in parallel planes with respect to the planar array of antenna elements to minimize connection lengths and associated losses. Thus, for example, each planar array of antenna elements and each RFFE IC may be considered to be essentially “2.5” dimensional objects with appreciable X and Y dimensions, but relatively small Z dimensions. An RF transceiver, receiver, or transmitter may include a substrate (e.g., a printed circuit board, PCB) having one or more antenna elements mounted in a first planar array on a surface, with one or more RFFE ICs each mounted with parallel X-Y dimensions (i.e., coaxial Z dimensions) adjacent one or more antenna elements. Each RFFE IC may be coupled to other ICs mounted on the substrate for modulation/demodulation of RF signals and general signal handling and control circuitry (noting that some of such pre-RFFE and/or post-RFFE functions may be instead embodied in an RFFE IC).

A problem that arises with such co-planar configurations of antenna elements and RFFE ICs is that, as RF frequencies increase, the X-Y size of the antenna elements decreases faster than the X-Y size of the associated RFFE IC dies decreases, to the point that at sufficiently high frequencies (e.g., above about 100 GHz), it may no longer be feasible to locate an RFFE IC on a PCB sufficiently close to associated antenna elements—in essence, the RFFE IC areas do not scale much with frequency while the antenna element size and spacing do, so that the total X-Y area of the RFFE ICs exceeds the X-Y area of the array of antenna elements.

Accordingly, there is a need for an antenna structure that can be located in close proximity with respect to an associated RFFE IC regardless of antenna element size.

### SUMMARY

The present invention encompasses antenna structures that can be located in close proximity with respect to an associated RFFE IC regardless of antenna element size. An antenna structure, including a grid or planar antenna or an array of antenna elements, is co-fabricated as part of or with one or more associated RFFE ICs using three-dimensional (3-D) stacking of IC dies, either directly or as part of an embedded die packaging technology.

Some embodiments include an IC including a substructure, a superstructure including multiple layers of dielectric, metallization layers, and conductive vias interconnecting the metallization layers, and at least one RF antenna element co-fabricated with the IC. In some embodiments, at least one of the RF antenna elements is configured to be electrically connectable to a corresponding RF antenna element in a second IC, wherein the IC and the second IC are coupled together by means of 3-D IC stacking.

Some embodiments utilize an embedded die packaging technology. For example, some embodiments include an embedded die package including at least one IC die, and at least one RF antenna element co-fabricated with the embedded die package and electrically connected to at least one of the at least one IC die.

Some embodiments include a combinable co-fabricated antenna element (CCAE), including at least one internally co-fabricated RF antenna element configured to be electrically connectable to a corresponding RF antenna element in a second combinable co-fabricated antenna element, wherein the combinable co-fabricated antenna element and the second combinable co-fabricated antenna element are couplable together by means of 3-D IC stacking.

Some embodiments include a plurality of combinable co-fabricated antenna elements coupled together by means of 3-D IC stacking such that the antenna elements form a grid antenna or comprise an array of antenna patches.

The details of one or more embodiments of the invention are set forth in the accompanying drawings and the description below. Other features, objects, and advantages of the invention will be apparent from the description and drawings, and from the claims.

### DESCRIPTION OF THE DRAWINGS

FIG. 1 is a block diagram of a prior art RF front end (RFFE) in a single transmitter, four-receiver configuration.

FIG. 2A is a cross-sectional side view of one embodiment of an IC die in accordance with the present invention, along a Y-Z dimensional plane.

FIG. 2B is a cross-sectional side view of one embodiment of an embedded IC die package in accordance with the present invention, along a Y-Z dimensional plane.

FIG. 3A is a top-front perspective view of a first embodiment of a 3-D IC that includes CCAE's in accordance with the present invention.

FIG. 3B is a bottom-rear perspective view of the stack of CCAE's in FIG. 3A.

FIG. 3C is a front elevation view of the stack of CCAE's in FIG. 3A.

FIG. 3D is a side elevation view of the stack of CCAE's in FIG. 3A.

FIG. 3E is a plan view of the stack of CCAE's in FIG. 3A.

FIG. 4 is a top-front perspective view of a second embodiment of the present invention, including a double stack of CCAE's.

FIG. 5 is a plan view of a third embodiment of a stack of CCAE's.

FIG. 6 is a plan view of a fourth embodiment of a stack of CCAE's.

FIG. 7 is a front elevation view of an alternative grid antenna configuration that may be fabricated as part of a CCAE.

FIG. 8 is a front elevation view of a fifth embodiment of a stack of CCAE's.

FIG. 9 is a top plan view of a substrate that may be, for example, a printed circuit board or die module substrate (e.g., a thin-film tile).

FIG. 10 illustrates a prior art wireless communication environment comprising different wireless communication systems, and which may include one or more mobile wireless devices.

FIG. 11 is a block diagram of a transceiver that might be used in a wireless device, such as a cellular telephone, and which may beneficially incorporate an embodiment of the present invention for improved performance.

FIG. 12 is a process flow chart showing a method of fabricating an integrated circuit.

FIG. 13 is a process flow chart showing a method of fabricating an embedded integrated circuit die package.

FIG. 14 is a process flow chart showing a first method of fabricating a combinable co-fabricated antenna element.

FIG. 15 is a process flow chart showing a second method of fabricating a combinable co-fabricated antenna element.

FIG. 16 is a process flow chart showing a third method of fabricating a combinable co-fabricated antenna element.

FIG. 17 is a process flow chart showing a first method of fabricating an antenna structure.

FIG. 18 is a process flow chart showing a second method of fabricating an antenna structure.

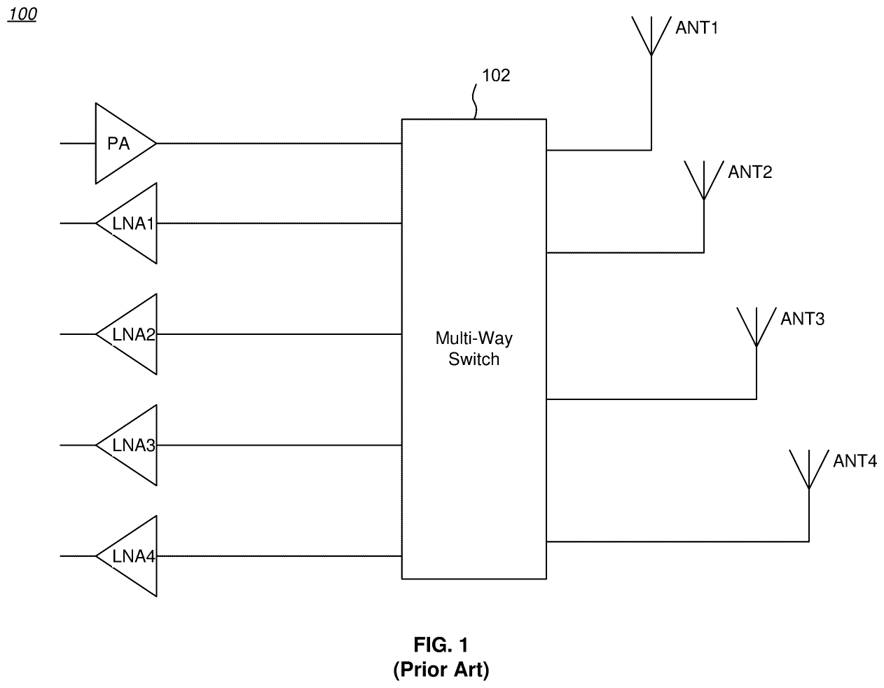

Like reference numbers and designations in the various drawings indicate like elements.

### DETAILED DESCRIPTION

The present invention encompasses antenna structures that can be located in close proximity with respect to an associated RFFE IC regardless of antenna element size. An antenna structure, including a grid or planar antenna or an array of antenna elements, is co-fabricated as part of or with one or more associated RFFE ICs using three-dimensional (3-D) stacking technology, either directly or as part of an embedded die packaging technology.

### MOSFET IC Fabrication

It may be useful to review how two-dimensional (2-D) metal-oxide-semiconductor field effect transistor (MOSFET) circuitry is fabricated using a conventional silicon-on-insulator (SOI) process. Starting with a wafer substrate, such as silicon, an insulating buried oxide (BOX) layer is formed, on which an active layer is formed, typically of doped silicon. On and/or within the active layer, one or more MOSFET structures are formed within the bounds of an individual IC die (unsingulated at this point). Each wafer substrate typically includes hundreds to thousands of unsingulated dies.

A MOSFET structure generally includes a mask-formed channel, a gate, a source, a drain, and isolation regions. The IC fabrication process up to this point is generally considered the front-end-of-line (FEOL) where individual devices (transistors, capacitors, resistors, inductors etc.) are patterned in or on the active layer. The FEOL generally covers everything up to (but not including) the deposition of metal interconnect layers, and may be regarded as fabrication of die substructures.

After the last FEOL step, a wafer contains multiple die regions each including isolated transistors without any interconnecting conductors. The back-end-of-line (BEOL) is the second portion of IC fabrication where the individual devices (transistors, capacitors, resistors, inductors, etc.) within a die region are interconnected with conductors formed as part of or spanning one or more metal interconnect layers. BEOL includes fabrication of electrical contacts (pads), vias, insulating layers (dielectrics), metallization layers, and bonding sites for die-to-package connections. In some applications, “through-substrate vias” (TSVs) may be fabricated, each TSV passing through the wafer substrate between the active layer and a connection point, such as a bond pad.

Some BEOL fabrication processes or post-BEOL fabrication processes (e.g., as part of outsourced semiconductor assembly and test) allow application of a redistribution layer (RDL), which is generally an extra patterned conductive layer (commonly aluminum) on an IC die that makes the input/output (I/O) pads of an IC die available to be coupled to other locations of the die, and/or to another IC die, and/or to specialized packaging structures. The RDL may be formed on top of the “upper” BEOL superstructure of an IC die. In some cases (for example, for single-layer transfer or SLT die structures), the RDL may be formed adjacent to a primary circuit layer containing active MOSFET regions after removal of the wafer substrate and re-attachment of the primary circuit layer and superstructure to a handle wafer.

Thus, a MOSFET IC die is essentially formed in two parts, a “lower” FEOL substructure and an “upper” BEOL superstructure formed in a die region of a substrate. After FEOL and BEOL processing, the wafer may undergo a number of additional process steps, including dicing, testing, and packaging, to form multiple IC dies.

### 3-D Stacking Technology

The electronics industry continues to strive for ever-increasing electronic functionality and performance in a wide variety of products, including (by way of example only) personal electronics (e.g., “smart” watches and fitness wearables), personal computers, tablet computers, wireless network components, televisions, cable system “set-top” boxes, radar systems, and cellular telephones. Increased functionality and/or performance commonly translates to more transistors and other electronic components on an IC die. While the number of transistors per unit area of an IC die has increased over time as IC manufacturing process nodes have shrunk device dimensions, the 2-D “footprint” of some IC dies has not decreased at the same rate, primarily owing to the use of more (albeit smaller) transistors to implement increased functionality and/or performance. The 2-D footprint of an IC die is one constraint on reducing the size of modules and circuit boards within products.

In order to shrink the 2-D footprint of an IC die, a number of 3-D technologies have been developed that have focused on stacking and bonding aligned IC dies originally fabricated on different wafers (also known as wafer-to-wafer bonding), stacking and bonding individual IC dies on non-singulated IC dies on a wafer (also known as die-to-wafer bonding), and stacking and bonding an individual IC die on another IC die (also known as die-to-die bonding). One such technology may be referred to as “hybrid bonding” (HB), in which the circuitry of a 2-D IC is divided and fabricated on different wafers or dies and then vertically stacked in a 3-D structure, with, for example, about half of the circuitry formed on a first or “bottom” wafer/die, and about half of the circuitry formed on a second or “top” wafer or die that is then bonded to the bottom wafer/die. Bonding of the two wafers/dies generally uses both dielectric materials (e.g., silicon dioxide, SiCN, SiCOH, and/or analogous dielectrics) and conductive interconnect materials (e.g., copper, aluminum, and/or their alloys). In general, a high density of interconnects between the top and bottom wafers/dies is desirable to achieve good communications between them. The interconnect pitch can be between about 0.2 to 10 μm, and preferably in approximately the 2-5 μm range. HB technology has a demonstrated high interconnect density, is a planar technology that does not require underfill or carrier wafer integration, and enables formation of interconnects between two IC wafers/dies during the bonding stage of processing at relatively low temperatures (e.g., <400) ° ° C.

Another technology for shrinking the 2-D footprint of an IC die utilizes 3-D embedded die packaging. For example, one or more individual IC dies may be embedded on one or more substrate layers (typically an organic material), with conductive pillar (e.g., copper) interconnects or “vias” connecting to other IC dies on stacked substrate layers or to connection points (e.g., bonding pads, bump, or pins) for external connections. The substrate layer on which an IC dies is embedded essentially functions as a printed circuit board, with the advantage of being able to be further processed to connect embedded ICs to other ICs on the same substrate layer or on different substrate layers, as well as to other types of components (e.g., capacitors, inductors, sensors, MEMS devices, etc.). Connections may be built up using conventional BEOL processes (e.g., sequential formation of one or more dielectric layers or conductive layers around an embedded IC die, including formation of interlayer connections such as vias) or by laminating multiple layers designed to accommodate an embedded IC die and containing horizontal and vertical conductors. After initial lamination, additional laminated layers may be added and/or conventional BEOL processes may be applied post-lamination to form additional structures, layers, and/or connection points.

### Co-Fabricated Antenna Arrays

Embodiments of the present invention utilize 3-D IC stacking or 3-D embedded die packaging along with BEOL or post-embedding processes to co-fabricate an antenna structure, which may comprise a grid or planar antenna or an array of antenna elements.

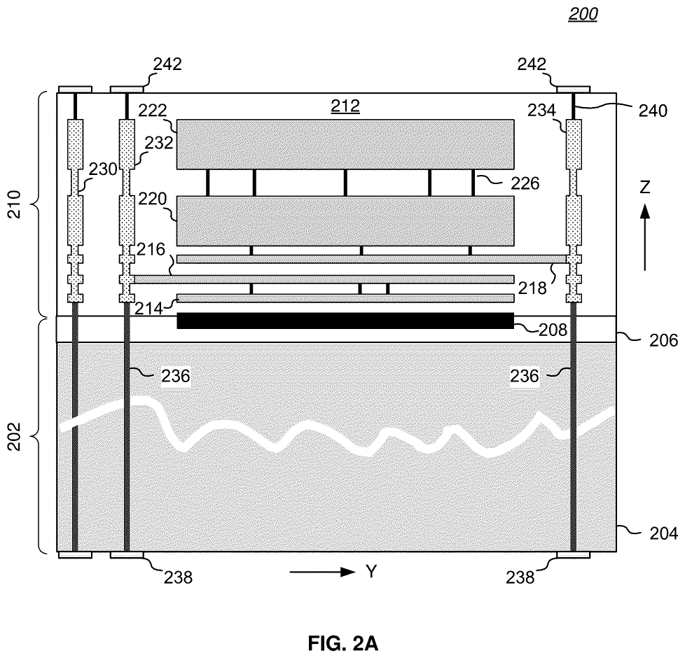

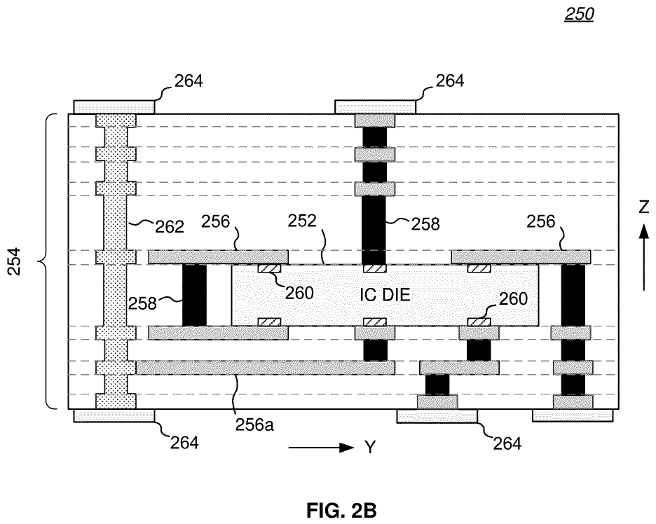

For example, FIG. 2A is a cross-sectional side view of one embodiment of an IC die 200 in accordance with the present invention, along a Y-Z dimensional plane. The X dimension is into the page. A conventional MOSFET substructure 202 comprises a wafer substrate 204 (e.g., Si, High-Resistance Si, etc.), an insulating buried oxide (BOX) layer 206, and an active layer 208, typically of doped silicon, generally containing multiple MOSFETs. As described above, the substructure 202 is fabricated as part of a FEOL process.

Formed on the substructure 202 is a superstructure 210 that comprises multiple sequential layers of dielectric layers 212, metallization layers 214-222, and conductive vias 226 interconnecting the metallization layers 214-222. The dielectric layers 212 are shown as an essentially continuous regions surrounding the metallization layers 214-222, and conductive vias 226. As described above, the superstructure 210 is fabricated as part of a BEOL process.

In some embodiments, the substructure 202 may be as thick as about 200 μm (hence the broken line to indicate much greater possible relative thickness) and as thin as about 2 μm (e.g., if the wafer substrate 204 is thinned). In some embodiments, the superstructure 210 may be as thick as about 9 μm.

In the illustrated example, also formed as part of the BEOL process are RF antenna elements 230-234 made of conductive material. The antenna elements 230-234 are generally formed using the same materials (e.g., Cu, Al) and sequential processes as the metallization layers 214-222 and conductive vias 226. In FIG. 2A, the antenna elements 230-234 are shaded differently from the metallization layers 214-222 only for purposes of contrast, but in some applications the antenna elements 230-234 may actually be made with different materials at the cost of extra masking steps and time.

Electrically connected to the antenna elements 230-234 are optional TSVs 236 coupled to substrate bonding pads 238, thus allowing connections to at least the antenna elements 230-234 from the “bottom” of the IC die 200. Optional vias 240 also couple the antenna elements 230-234 to superstructure bonding pads 242, thus allowing connections to at least the antenna elements 230-234 from the “top” of the IC die 200.

FIG. 2A does not show the X-dimension of the IC die 200, but as will become clear from following figures, the antenna elements 230-234 may extend along the X-dimension of the IC die 200.

In the illustrated example, metallization layer 216 is electrically coupled to antenna element 232, and metallization layer 218 is electrically coupled to antenna element 234. Antenna element 230 may be coupled to a metallization layer somewhere else along the X-dimension of the IC die 200. The active layer 208 may include RFFE components, such as a multi-way switch, one or more low-noise amplifiers (LNAs), and/or one or more power amplifiers (PAs). Thus, the IC die 200 as illustrated in FIG. 2A comprises three complete antenna elements 230-234 and may include the necessary RFFE components to replace an RFFE die and external antenna element. As should be appreciated, the designed size of the antenna elements 230-234 may be adjusted as needed for a particular frequency range, generally being designed to be smaller as frequency increases. In some embodiments, an IC die 200 may be fabricated without active circuitry but with one or more antenna elements (see below for details of usage of such a structure).

As another example, FIG. 2B is a cross-sectional side view of one embodiment of an embedded IC die package 250 in accordance with the present invention, along a Y-Z dimensional plane. An IC die 252 is embedded in known fashion within a stack of planar lamination layers 254 (cach layer indicated by a dashed line) that include horizontal (in-plane) conductors 256 and vertical (perpendicular-to-plane) conductors or vias 258. In the illustrated example, some of the horizontal conductors 256 contact die pads 260 that form part of the IC die 252.

An antenna element 262 is co-fabricated (i.e., concurrently formed) by portions of the horizontal and vertical conductors (however, the antenna element 262 is shaded differently from the horizontal and vertical conductors 256, 258 for purposes of contrast). Bonding pads 264 are shown formed on the top and bottom surfaces of the lamination layers 254, thus allowing connections to at least the antenna element 262. The antenna element 262 may be coupled to the IC die 252 by one or more horizontal and/or vertical conductors 256, 258. The completed embedded IC die package 250 may be utilized thereafter like an integrated circuit and attached to other structures, such as interposers, die modules, or PCBs.

FIG. 2B does not show the X-dimension of the embedded IC die package 250, but as will become clear from following figures, the antenna element 262 may extend along the X-dimension of the embedded IC die package 250.

The antenna element 262 is thus external to the embedded IC die 252 but encompassed and integrally formed within the embedded IC die package 250. In some applications, more than one antenna element 262 may be formed within an embedded IC die package 250. In some applications, more than one IC die 252 may be embedded in the same embedded IC die package 250. In some embodiments, the embedded IC die package 250 may be as thick as about 400-500 μm. In some embodiments, a die package like the embedded IC die package 250 may be fabricated without an embedded IC die 252 but with one or more antenna elements 262 (see below for details of usage of such a structure).

In the illustrated example, the antenna element 262 is coupled to the IC die 252 by a horizontal conductor 256a. The antenna element 262 may also be coupled to the IC die 252 somewhere else along the X-dimension of the embedded IC die package 250. The IC die 252 may include RFFE components, such as a multi-way switch, one or more LNAs, and/or one or more PAs. Thus, the embedded IC die package 250 as illustrated in FIG. 2B comprises one complete antenna element 262 and may include the necessary RFFE components to replace an RFFE die and external antenna element. As should be appreciated, the designed size of the antenna element 262 may be adjusted as needed for a particular frequency range, generally being designed to be smaller as frequency increases.

It should be appreciated that either of the structures illustrated in FIGS. 2A and 2B can provide close proximity of an antenna element to an active circuitry region (e.g., co-fabricated IC MOSFETs or an embedded IC die). Close proximity is particularly useful at high frequencies, especially above about 100 GHz, in order to reduce parasitic resistances, inductances, and capacitances. Further, FIGS. 2A and 2B visually indicate that the antenna element sizing is constrained only by the X (into the page) and Z axes while the co-fabricated RFFE IC circuitry may expand along either or both of the X and Y axes without regard to the size of the antenna element or elements, which is particularly useful for antenna arrays designed for frequencies at or above around 100 GHz. Essentially, the co-fabricated RFFE IC circuitry is perpendicular (rather than co-planar) with respect to the antenna elements.

### Combinable Co-fabricated Antenna Elements

For purposes of this disclosure, the terms “CCAE” and “combinable co-fabricated antenna element” are collective terms for (1) an IC die 200 that includes all or part of at least one internally co-fabricated antenna element (e.g., antenna elements 230-234 in FIG. 2A) and may include MOSFET circuitry, and/or (2) an embedded IC die package 250 that includes all or part of at least one co-fabricated antenna element (e.g., antenna element 262 in FIG. 2B) and may include an embedded IC die 252.

An important aspect of the present invention is that combinable co-fabricated antenna elements (CCAE's) may be combined by a 3-D stacking technology so as to form a larger antenna structure, such as a grid antenna or an array of antenna elements. In some embodiments, the CCAE's need not be all of the same type. Thus, for example, a grid antenna or an array of antenna elements may be built up using a combination of IC dies 200 that include at least one internally co-fabricated antenna element and embedded IC die packages 250 that include at least one co-fabricated antenna element. Stacking may be accomplished by any of the technologies described above, or equivalents, including (but not limited to) wafer-to-wafer bonding, die-to-wafer bonding. die-to-die bonding, and 3-D embedded die packaging. An advantage of such stacking is that the 2-D footprint of the stacked CCAE's is substantially reduced by a factor of the number of CCAE's within a stack. For example, 6 vertically stacked CCAE's (along Z direction) would have the same 2-D footprint (X-Y footprint) as a single CCAE.

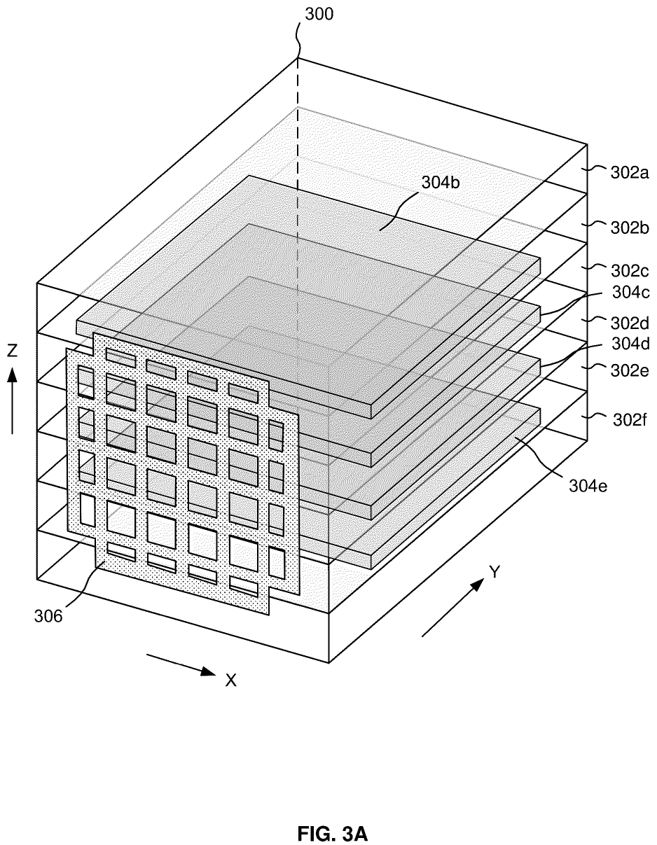

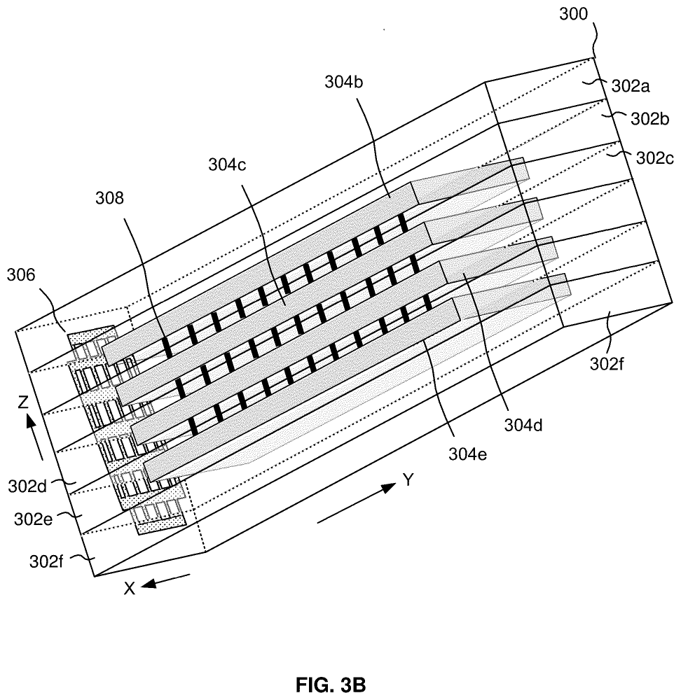

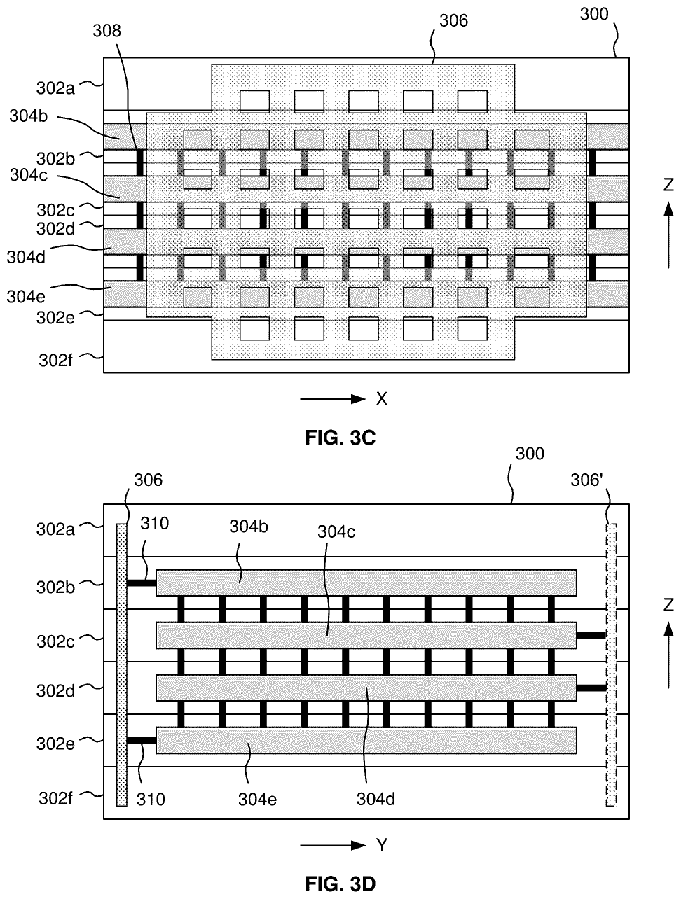

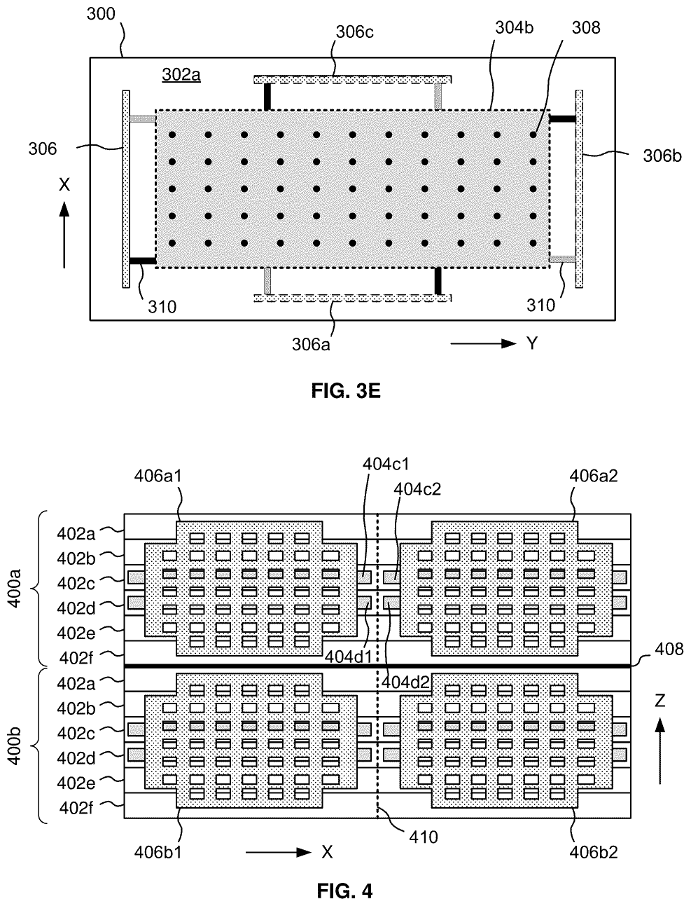

FIG. 3A is a top-front perspective view of a first embodiment of a 3-D IC that includes CCAE's 302a-302f in accordance with the present invention. In the illustrated example, the top and bottom CCAE's 302a, 302f include only a co-fabricated antenna element (i.e., no active circuitry), while the interior CCAE's 302b-302e of the stack each include respective active circuitry regions 304b-304c (which would be in the form of a region of active circuitry such as MOSFETS for an IC die 200, and in the form of an entire IC in the case of an embedded IC die package 250). The CCAE's are stacked so that internal antenna elements (e.g., antenna element 230 in FIG. 2A, antenna element 262 in FIG. 2B) align and are electrically coupled (e.g., through bonding of aligned bonding pads 264 in the case of embedded IC die packages 250, or aligned pairs of substrate bonding pads 238 and superstructure bonding pads 242 in the case of IC dies 200). To avoid clutter, vias between the CCAE's 302a-302f are not shown.

In the illustrated example, the inter-connected antenna elements of the CCAE's 302a-302f form a grid antenna 306. If the fabrication process allows sufficiently dense conductive pat-terns for the co-fabricated antenna elements within each CCAE, the inter-connected antenna elements of the CCAE's 302a-302f may form an antenna that comprises—or closely approaches—a solid planar antenna. An advantage of the side location of the grid antenna 306 (e.g., in the X-Z plane) is that when the stack of CCAE's 302a-302f is mounted in a module or on a PCB, the generally orthogonal grid antenna 306 may be positioned to receive and transmit RF signals to the side of a product, such as the edge of a cell phone, where RF signal passage may be less impeded by other product structures and circuits.

FIG. 3B is a bottom-rear perspective view of the stack 300 of CCAE's 302a-302f in FIG. 3A. In the illustrated example, vias 308 between the CCAE's 302a-302f are shown but connections between the grid antenna 306 and the active circuitry regions 304b-304e are omitted.

FIG. 3C is a front elevation view of the stack 300 of CCAE's 302a-302f in FIG. 3A. This view shows the X-dimension span of the antenna elements comprising the grid antenna 306. Note that while the grid antenna 306 is shown as a single grid, in some embodiments, the single illustrated grid antenna 306 may be subdivided into two or more grid antennas. For example, the illustrated grid antenna 306 may be subdivided into two co-planar spaced-apart grid antennas by simply reconfiguring which CCAE's 302a-302f are connected to each other.

FIG. 3D is a side elevation view of the stack 300 of CCAE's 302a-302f in FIG. 3A. This view shows electrical connections 310 between the grid antenna 306 and the active circuitry regions 304b-304e, but the vias between the CCAE's 302a-302f are not labeled to avoid clutter. Also shown is an optional second grid antenna 306′, co-fabricated in the same manner as the grid antenna 306.

FIG. 3E is a plan view of the stack 300 of CCAE's 302a-302f in FIG. 3A. The topmost active circuitry region 304b is shown in dotted phantom outline. Also shown are optional grid antennas 306a-306c which may be co-fabricated in the same manner as the grid antenna 306; the number of additional grid antennas 306a-306c, if any, will depend on a particular design goal. Electrical connections 310 between the grid antenna 306 and the active circuitry regions 304b-304e (see FIGS. 3A-3D) are shown in two different shadings, indicating that the connections may be made at different layers of the stack 300 of CCAE's 302a-302f.

FIG. 4 is a top-front perspective view of a second embodiment of the present invention, including a double stack 400a, 400b of CCAE's 402a-402f. Each stack 400a, 400b includes respective side-by-side grid antennas 406a1, 406a2 and 406b1, 406b2 formed from respective portions of the co-fabricated antenna elements within the CCAE's 402a-402f. In alternative embodiments, one or more of the stacks 400a, 400b may include only one grid antenna or more than two grid antennas. The stacks 400a, 400b may be connected directly using a 3-D stacking technology described above, or an equivalent technology, or through a conventional electrical interface (e.g., an interposer) for routing electrical connections between one IC-like structure to another IC-like structure. For example, in FIG. 4, an interposer may be positioned at the interface 408 between stack 400a and stack 400b.

In the illustrated example, each CCAE stack 400a, 400b includes four active circuitry regions, each of which would be in the form of a region of active circuitry such as MOSFETs for an IC die 200, and in the form of an entire IC in the case of an embedded IC die package 250. In the illustrated example, two side-by-side pairs of active circuitry regions 404c1, 404c2 and 404d1, 404d2 are located within respective CCAEs 402c, 404d.

In an alternative embodiment, the structure shown in FIG. 4 may be constructed by using four “unit cells”, each comprising a stack of CCAE's 402a-402f and associated active circuitry regions (e.g., 404cl and 404d1), but without side-by-side pairs of active circuitry regions or dual antenna elements (thus effectively splitting the illustrated CCAE stacks 400a, 400b along dotted line 410). Connections may be made between the unit cells in the horizontal and vertical directions through, for example, an interposer positioned at the interface 408 between the upper unit cells and the lower unit cells.

The configuration illustrated in FIG. 4 also shows that one IC die or IC die package (e.g., IC die 200 from FIG. 2A or IC die package 250 from FIG. 2B) may include more than one antenna element, and that one embedded IC die package 250 may include more than one embedded IC die 252, each with all or part of at least one associated antenna element.

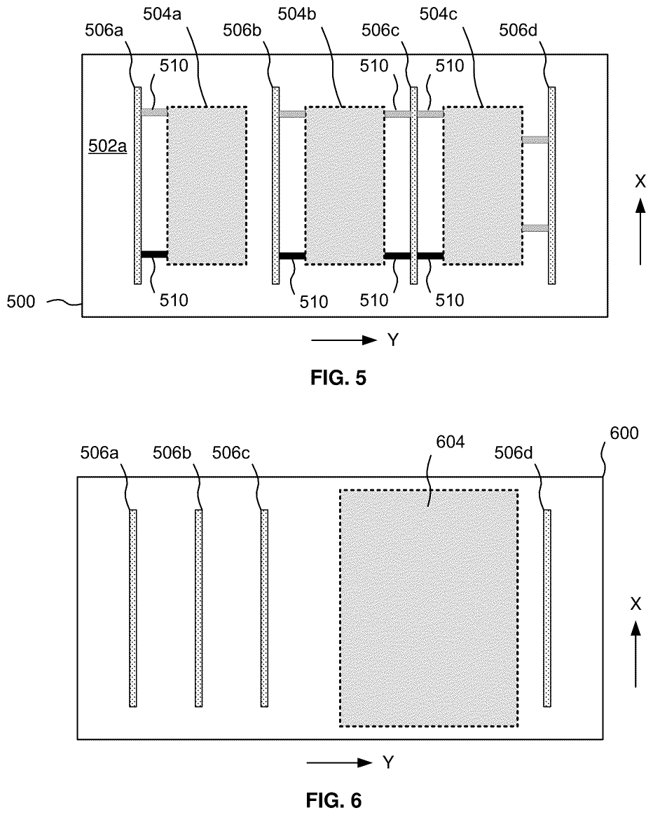

FIG. 5 is a plan view of a third embodiment of a stack 500 of CCAE's. In the illustrated example, there are three active circuitry regions 504a-504c (shown in dotted phantom outline) and four grid antennas 506a-506d. The illustrated configuration shows that grid antennas may be formed between active circuitry regions (which, for this example, would be in the form of three spaced-apart regions of active circuitry for an IC die 200, and in the form of three distinct ICs in the case of an embedded IC die package 250). The illustrated configuration also shows that multiple grid antennas (e.g., grid antennas 506b, 506c) may be coupled through connectors 510 to one active circuitry region 504b, and that one antenna element (e.g., grid antenna 506c) may be coupled to more than one active circuitry region (e.g., active circuit regions 504b, 504c). As noted above, in some embodiments, an antenna element may not connect to any active circuitry region within a particular CCAE.

FIG. 6 is a plan view of a fourth embodiment of a stack 600 of CCAE's. In the illustrated example, there is one active circuitry region 604 (shown in dotted phantom outline) and four grid antennas 506a-506d (connectors from the active circuitry region 604 to the grid antennas 506a-506d have been omitted for clarity). The illustrated configuration shows that grid antennas 506a-506d may be formed with a non-uniform spacing (in this example, non-uniform in the Y dimension). As noted above, in some embodiments, an antenna element may not connect to any active circuitry region within a particular CCAE.

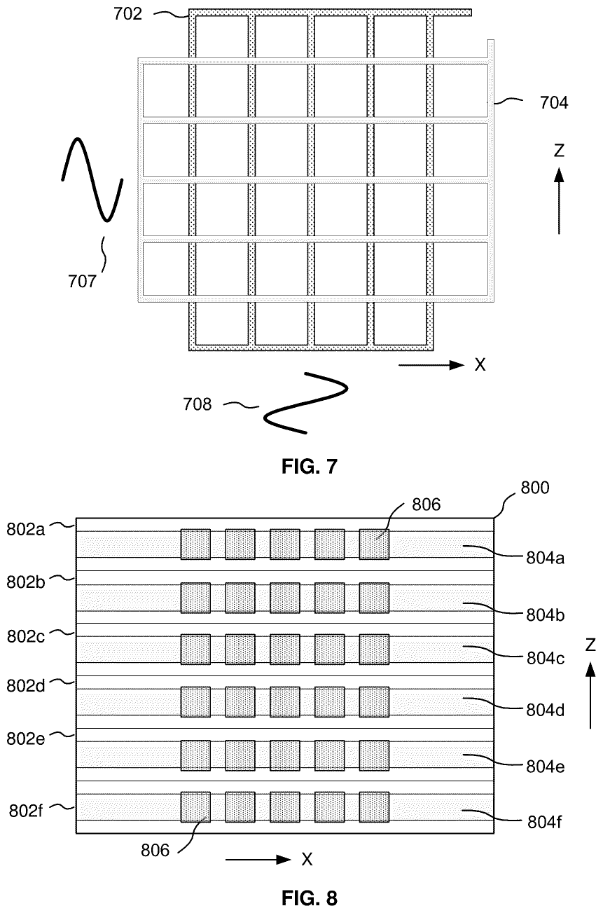

The single grid antenna shown in FIG. 3A can support the reception and/or transmission of dual polarized signals. However, it may be desirable to use separate grid antennas, for example, to increase isolation between polarizations. FIG. 7 is a front elevation view of an alternative grid antenna configuration that may be fabricated as part of a CCAE. In the illustrated example, a first grid antenna 702 is fabricated with primarily vertical members, and a second antenna 704 is fabricated with primarily horizonal members and spaced apart from the first grid antenna 702 (for simplicity, the associated structure that includes any active circuitry region is omitted). The two separate antenna grids 702, 704 can thus support dual polarization, with the first grid antenna 702 being most sensitive to vertically polarized RF signals 706, and the second grid antenna 704 being most sensitive to horizontally polarized RF signals.

FIG. 8 is a front elevation view of a fifth embodiment of a stack 800 of CCAE's 802a-802f. In the illustrated example, each CCAE 802a-802f includes an active circuitry region 804a-804f. Further, rather than form joined antenna elements in each CCAE 802a-802f, multiple spaced-apart antenna elements or “patches” 806 are co-fabricated within each CCAE 802a-802f and electrically connected to an associated active circuitry region 804a-804f. When the CCAE's 802a-802f are stacked, the antenna patches 806 form an array of antenna elements that may be utilized as a phased-array antenna. In general, it is useful to space the antenna patches apart by less than or equal to one-half the wavelength of a target frequency (e.g., for 150 GHz RF signals, the target frequency wavelength is about 2 mm, so the spacing S between antenna patches should be about S=1 mm). As is known in the art, an array of antenna elements may be used with phased-array RF circuitry to enable beam steering.

While the embodiments described in FIGS. 3A-3E & 4-8 illustrate combinations of CCAE's, in some applications, an individual CCAE may be used as an integrated antenna and RFFE IC, for example, where the co-fabricated antenna element is sufficiently large to perform adequately in a selected frequency range without the need to enlarge the antenna structure by combining CCAE's.

### Circuit Embodiments

Circuits and devices in accordance with the present invention may be used alone or in combination with other components, circuits, and devices. Embodiments of the present invention may be fabricated as integrated circuits (ICs), which may be encased in IC packages and/or in modules for case of handling, manufacture, and/or improved performance. In particular, IC embodiments of this invention are often used in modules in which one or more of such ICs are combined with other circuit components or blocks (e.g., filters, amplifiers, passive components, and possibly additional ICs) into one package. The ICs and/or modules are then typically combined with other components, often on a printed circuit board, to form part of an end-product such as a cellular telephone, laptop computer, or electronic tablet, or to form a higher-level module which may be used in a wide variety of products, such as vehicles, test equipment, medical devices, etc. Through various configurations of modules and assemblies, such ICs typically enable a mode of communication, often wireless communication.

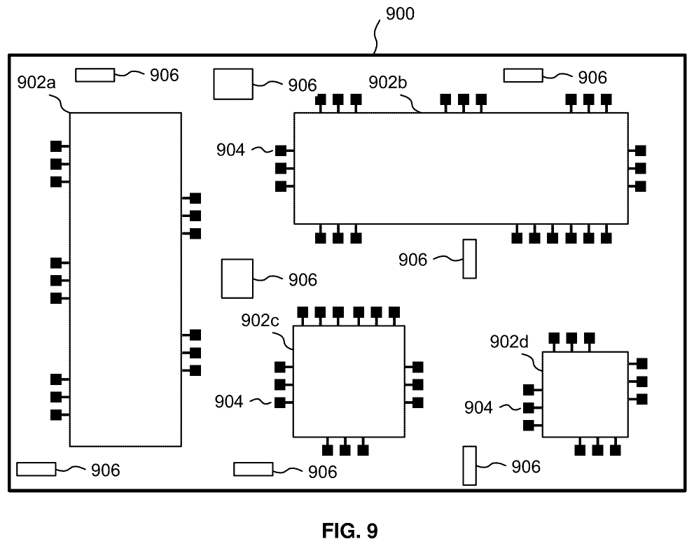

As one example of further integration of embodiments of the present invention with other components, FIG. 9 is a top plan view of a substrate 900 that may be, for example, a printed circuit board or die module substrate (e.g., a thin-film tile). In the illustrated example, the substrate 900 includes multiple ICs 902a-902d having terminal pads 904 which would be interconnected by conductive vias and/or traces on and/or within the substrate 900 or on the opposite (back) surface of the substrate 900 (to avoid clutter, the surface conductive traces are not shown and not all terminal pads are labelled). The ICs 902a-902d may embody, for example, signal switches, active filters, amplifiers (including one or more LNAs), and other circuitry. For example, IC 902b may be a stack of CCAE's such as shown in FIGS. 3A-3E and 4-8.

The substrate 900 may also include one or more passive devices 906 embedded in, formed on, and/or affixed to the substrate 900. While shown as generic rectangles, the passive devices 906 may be, for example, filters, capacitors, inductors, transmission lines, resistors, planar antennae elements, transducers (including, for example, MEMS-based transducers, such as accelcrometers, gyroscopes, microphones, pressure sensors, etc.), batteries, etc., interconnected by conductive traces on or in the substrate 900 to other passive devices 906 and/or the individual ICs 902a-902d. The front or back surface of the substrate 900 may be used as a location for the formation of other structures.

### System Aspects

Embodiments of the present invention are useful in a wide variety of larger radio RF circuits and systems for performing a range of functions, including (but not limited to) impedance matching circuits, RF PAS, RF LNAs, phase shifters, attenuators, antenna beam-steering systems, charge pump devices, RF switches, etc. Such functions are useful in a variety of applications, such as radar systems (including phased array and automotive radar systems), radio systems (including cellular radio systems), and test equipment.

Radio system usage includes wireless RF systems (including base stations, relay stations, and hand-held transceivers) that use various technologies and protocols, including various types of orthogonal frequency-division multiplexing (“OFDM”), quadrature amplitude modulation (“QAM”), Code-Division Multiple Access (“CDMA”), Time-Division Multiple Access (“TDMA”), Wide Band Code Division Multiple Access (“W-CDMA”), Global System for Mobile Communications (“GSM”), Long Term Evolution (“LTE”), 5G New Radio, 6G, and WiFi (e.g., 802.11a, b, g, ac, ax, be) protocols, as well as other radio communication standards and protocols.

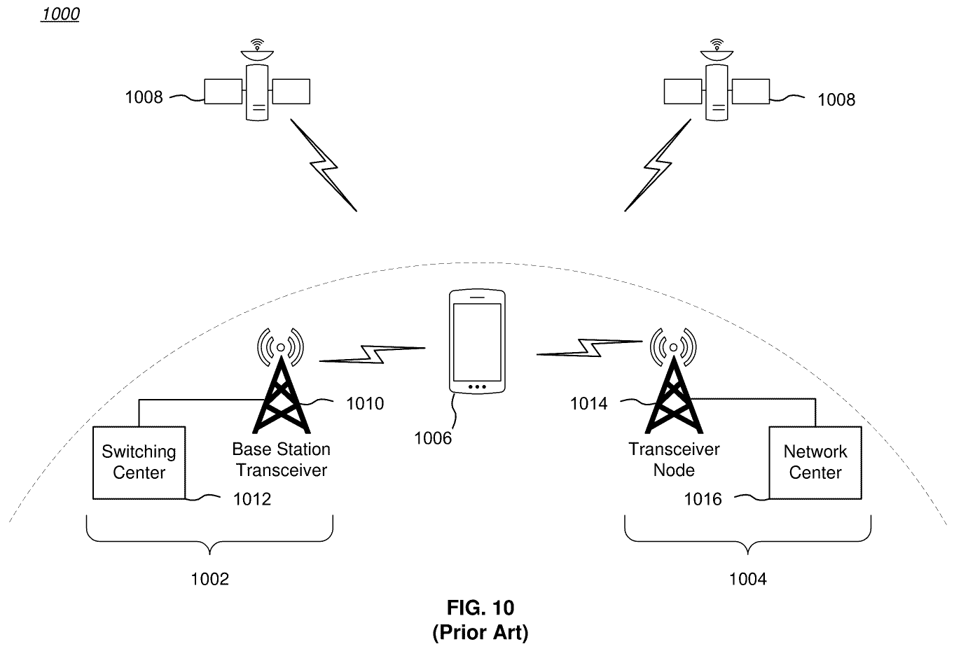

As an example of wireless RF system usage, FIG. 10 illustrates a prior art wireless communication environment 1000 comprising different wireless communication systems 1002 and 1004, and which may include one or more mobile wireless devices 1006. A wireless device 1006 may be a cellular phone, a wireless-enabled computer or tablet, or some other wireless communication unit or device. A wireless device 1006 may also be referred to as a mobile station, user equipment, an access terminal, or some other terminology known in the telecommunications industry.

A wireless device 1006 may be capable of communicating with multiple wireless communication systems 1002, 1004 using one or more of telecommunication protocols such as the protocols noted above. A wireless device 1006 also may be capable of communicating with one or more satellites 1008, such as navigation satellites (e.g., GPS) and/or telecommunication satellites. The wireless device 1006 may be equipped with multiple antennas, externally and/or internally, for operation on different frequencies and/or to provide diversity against deleterious path effects such as fading and multi-path interference.

The wireless communication system 1002 may be, for example, a CDMA-based system that includes one or more base station transceivers (BSTs) 1010 and at least one switching center (SC) 1012. Each BST 1010 provides over-the-air RF communication for wireless devices 1006 within its coverage area. The SC 1012 couples to one or more BSTs 1010 in the wireless system 1002 and provides coordination and control for those BSTs 1010.

The wireless communication system 1004 may be, for example, a TDMA-based system that includes one or more transceiver nodes 1014 and a network center (NC) 1016. Each transceiver node 1014 provides over-the-air RF communication for wireless devices 1006 within its coverage area. The NC 1016 couples to one or more transceiver nodes 1014 in the wireless system 1004 and provides coordination and control for those transceiver nodes 1014.

In general, each BST 1010 and transceiver node 1014 is a fixed station that provides communication coverage for wireless devices 1006, and may also be referred to as base stations or some other terminology known in the telecommunications industry. The SC 1012 and the NC 1016 are network entities that provide coordination and control for the base stations and may also be referred to by other terminologies known in the telecommunications industry.

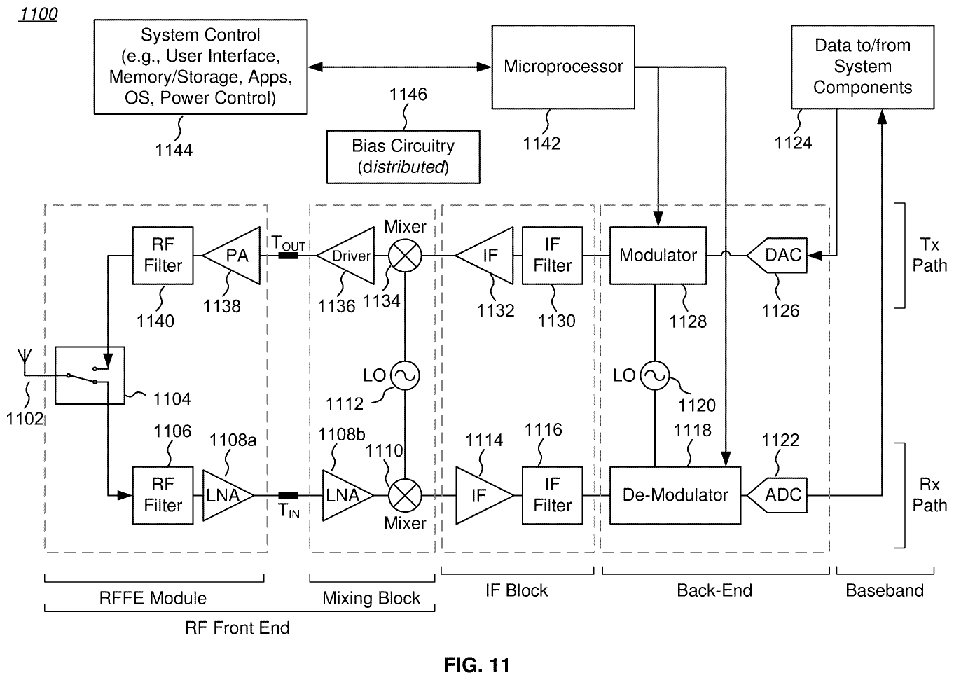

An important aspect of any wireless system, including the systems shown in FIG. 10, is in the details of how the component elements of the system perform. FIG. 11 is a block diagram of a transceiver 1100 that might be used in a wireless device, such as a cellular telephone, and which may beneficially incorporate an embodiment of the present invention for improved performance. As illustrated, the transceiver 1100 includes a mix of RF analog circuitry for directly conveying and/or transforming signals on an RF signal path, non-RF analog circuitry for operational needs outside of the RF signal path (e.g., for bias voltages and switching signals), and digital circuitry for control and user interface requirements. In this example, a receiver path Rx includes RF Front End (RFFE), Intermediate Frequency (IF) Block, Back-End, and Baseband sections (noting that in some implementations, the differentiation between sections may be different). The various illustrated sections and circuit elements may be embodied in one die or multiple IC dies. For example, the RF Front End in the illustrated example may include an RFFE module and a Mixing Block, which may be embodied in (or as part of) different IC dies or modules. The different dies and/or modules may be coupled by transmission lines TIN and TOUT (e.g., microstrips, co-planar waveguides, or an equivalent structure or circuit), either or both of which may have, for example, a 5052 impedance.

The receiver path Rx receives over-the-air RF signals through at least one antenna 1102 and a switching unit 1104, which may be implemented with active switching devices (e.g., field effect transistors or FETs) and/or with passive devices that implement frequency-domain multiplexing, such as a diplexer or duplexer. The antenna 1102 may be a grid antenna or an array of antenna elements in accordance with the teachings of this disclosure. An RF filter 1106 passes desired received RF signals to at least one LNA 1108a, the output of which is coupled from the RFFE Module to at least one LNA 1108b in the Mixing Block (through transmission line TIN in this example). The LNA(s) 1108b may provide buffering, input matching, and reverse isolation. The switching unit 1104, RF filter 1106, and the at least one LNA 1108a, as well as other circuitry within the Mixing Block and/or IF Block, may be fabricated as part of an active circuitry region of a CCAE.

The output of the LNA(s) 1108b is combined in a corresponding mixer 1110 with the output of a first local oscillator 1112 to produce an IF signal. The IF signal may be amplified by an IF amplifier 1114 and subjected to an IF filter 1116 before being applied to a demodulator 1118, which may be coupled to a second local oscillator 1120. The demodulated output of the demodulator 1118 is transformed to a digital signal by an analog-to-digital converter 1122 and provided to one or more system components 1124 (e.g., a video graphics circuit, a sound circuit, memory devices, etc.). The converted digital signal may represent, for example, video or still images, sounds, or symbols, such as text or other characters.

In the illustrated example, a transmitter path Tx includes Baseband, Back-End, IF Block, and RF Front End sections (again, in some implementations, the differentiation between sections may be different). Digital data from one or more system components 1124 is transformed to an analog signal by a digital-to-analog converter 1126, the output of which is applied to a modulator 1128, which also may be coupled to the second local oscillator 1120. The modulated output of the modulator 1128 may be subjected to an IF filter 1130 before being amplified by an IF amplifier 1132. The output of the IF amplifier 1132 is then combined in a mixer 1134 with the output of the first local oscillator 1112 to produce an RF signal. The RF signal may be amplified by a driver 1136, the output of which is coupled to a power amplifier (PA) 1138 (through transmission line Tour in this example). The amplified RF signal may be coupled to an RF filter 1140, the output of which is coupled to at least one antenna 1102 through the switching unit 1104. The switching unit 1104, RF filter 1140, and the PA 1138, as well as other circuitry, may be fabricated as part of an active circuitry region of a CCAE.

The operation of the transceiver 1100 is controlled by a microprocessor 1142 in known fashion, which interacts with system control components 1144 (e.g., user interfaces, memory/storage devices, application programs, operating system software, power control, etc.). In addition, the transceiver 1100 will generally include other circuitry, such as bias circuitry 1146 (which may be distributed throughout the transceiver 1100 in proximity to transistor devices), electro-static discharge (ESD) protection circuits, testing circuits (not shown), factory programming interfaces (not shown), etc.

In modern transceivers, there are often more than one receiver path Rx and transmitter path Tx, for example, to accommodate multiple frequencies and/or signaling modalities. Further, as should be apparent to one of ordinary skill in the art, some components of the transceiver 1100 may be positioned in a different order (e.g., filters) or omitted. Other components can be (and often arc) added, such as (by way of example only) additional filters, impedance matching networks, variable phase shifters/attenuators, power dividers, etc.

Embodiments of the current invention reduce sizing of and spacing between antenna elements and associated active circuitry regions independently of IC die area by essentially co-fabricating RFFE IC circuitry perpendicular to (rather than co-planar with) the antenna elements, thereby improving performance. Embodiments of the current invention further allow grid antennas or an array of antenna elements to be proportioned in size as may be required for operation in high frequency ranges (e.g., at or above about 100 GHz) and enable a small 2-D footprint. As a person of ordinary skill in the art will understand, a system architecture is beneficially impacted by the current invention in critical ways, including reduced parasitics, better range, better reception, lower power, longer battery life, and wider bandwidth.

### Methods

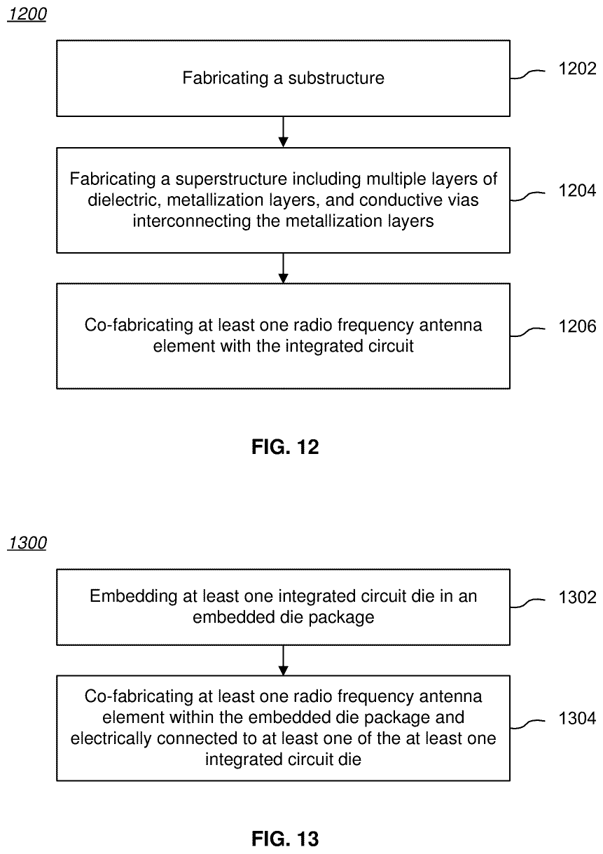

Another aspect of the invention includes methods for fabricating integrated circuits that include a co-fabricated RF antenna element. For example, FIG. 12 is a process flow chart 1200 showing a method of fabricating an integrated circuit including: fabricating a substructure (Block 1202); fabricating a superstructure including multiple layers of dielectric, metallization layers, and conductive vias interconnecting the metallization layers (Block 1204); and co-fabricating at least one radio frequency antenna element with the integrated circuit (Block 1206).

FIG. 13 is a process flow chart 1300 showing a method of fabricating an embedded integrated circuit die package including: embedding at least one integrated circuit die in an embedded die package (Block 1302); and co-fabricating at least one radio frequency antenna element within the embedded die package and electrically connected to at least one of the at least one integrated circuit die (Block 1304).

Additional aspects of the above methods may include one or more of the following: wherein the substructure includes an active layer containing multiple MOSFETs; further including configuring at least one of the at least one radio frequency antenna element to be electrically connectable to a corresponding radio frequency antenna element in a second integrated circuit by means of 3-D integrated circuit stacking; wherein at least one of the at least one integrated circuit die includes multiple MOSFETs; and/or further including configuring at least one of the at least one radio frequency antenna element to be electrically connectable to a corresponding radio frequency antenna element in a second embedded die package by means of 3-D integrated circuit stacking.

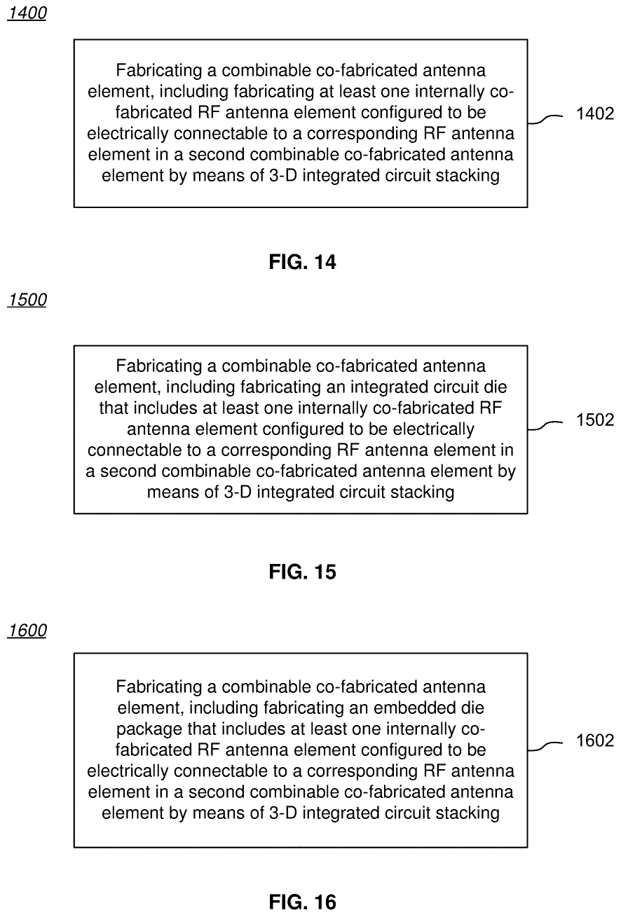

FIG. 14 is a process flow chart 1400 showing a first method of fabricating a combinable co-fabricated antenna element, including fabricating at least one internally co-fabricated radio frequency antenna element configured to be electrically connectable to a corresponding radio frequency antenna element in a second combinable co-fabricated antenna element by means of 3-D integrated circuit stacking (Block 1402).

FIG. 15 is a process flow chart 1500 showing a second method of fabricating a combinable co-fabricated antenna element, including fabricating an integrated circuit die that includes at least one internally co-fabricated radio frequency antenna element configured to be electrically connectable to a corresponding radio frequency antenna element in a second combinable co-fabricated antenna element by means of 3-D integrated circuit stacking (Block 1502).

FIG. 16 is a process flow chart 1600 showing a third method of fabricating a combinable co-fabricated antenna element, including fabricating an embedded die package that includes at least one internally co-fabricated radio frequency antenna element configured to be electrically connectable to a corresponding radio frequency antenna element in a second combinable co-fabricated antenna element by means of 3-D integrated circuit stacking (Block 1602).

Additional aspects of the above methods may include one or more of the following: wherein the combinable co-fabricated antenna element further includes an active circuitry region; wherein the integrated circuit die further includes an active layer containing multiple MOSFETs; and/or wherein the embedded die package includes at least one integrated circuit die, and at least one of the at least one integrated circuit die includes multiple MOSFETs.

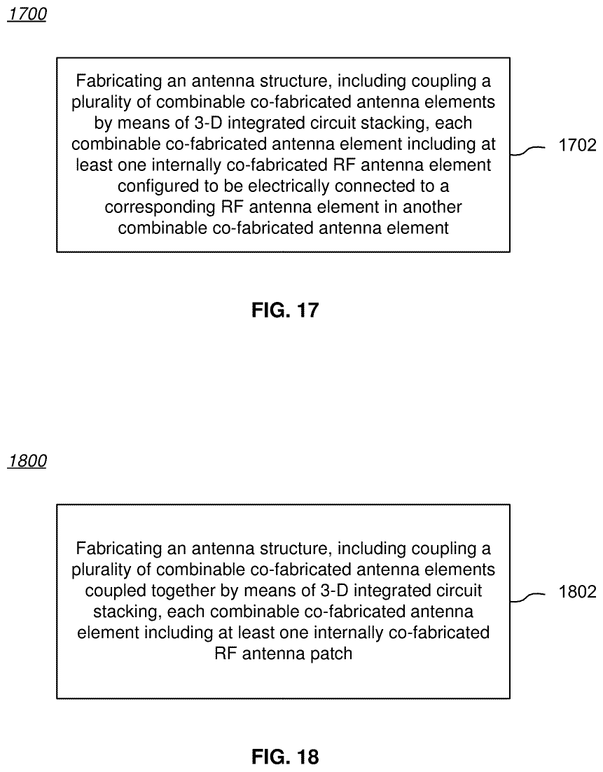

FIG. 17 is a process flow chart 1700 showing a first method of fabricating an antenna structure, including coupling a plurality of combinable co-fabricated antenna elements by means of 3-D integrated circuit stacking, each combinable co-fabricated antenna element including at least one internally co-fabricated radio frequency antenna element configured to be electrically connected to a corresponding radio frequency antenna element in another combinable co-fabricated antenna element (Block 1702).

FIG. 18 is a process flow chart 1800 showing a second method of fabricating an antenna structure, including coupling a plurality of combinable co-fabricated antenna elements coupled together by means of 3-D integrated circuit stacking, each combinable co-fabricated antenna element including at least one internally co-fabricated radio frequency antenna patch (Block 1802).

Additional aspects of the above methods may include one or more of the following: wherein the electrically connected radio frequency antenna elements of the plurality of combinable co-fabricated antenna elements form a grid antenna; wherein each combinable co-fabricated antenna element includes a plurality of radio frequency antenna patches; wherein a combination of the radio frequency antenna patches of the plurality of combinable co-fabricated antenna elements forms an antenna array; wherein at least one of the plurality of combinable co-fabricated antenna elements includes an active circuitry region; wherein at least one of the plurality of combinable co-fabricated antenna elements includes a radio frequency integrated circuit including the at least one internally co-fabricated radio frequency antenna element; wherein at least one of the plurality of combinable co-fabricated antenna elements includes an embedded die package including the at least one internally co-fabricated radio frequency antenna element; and/or wherein the internally co-fabricated radio frequency antenna elements define a first plane, and wherein at least one of the plurality of combinable co-fabricated antenna elements includes an active circuitry region defining a second plane extending essentially perpendicular to the first plane.

Fabrication Technologies & Options

The term “MOSFET”, as used in this disclosure, includes any FET having an insulated gate whose voltage determines the conductivity of the transistor, and encompasses insulated gates having a metal or metal-like, insulator, and/or semiconductor structure. The terms “metal” or “metal-like” include at least one electrically conductive material (such as aluminum, copper, or other metal, or highly doped polysilicon, graphene, or other electrical conductor), “insulator” includes at least one insulating material (such as silicon oxide or other dielectric material), and “semiconductor” includes at least one semiconductor material.

As used in this disclosure, the term “radio frequency” (RF) refers to a rate of oscillation in the range of about 3 kHz to about 300 GHz. This term also includes the frequencies used in wireless communication systems. An RF frequency may be the frequency of an electromagnetic wave or of an alternating voltage or current in a circuit.

With respect to the figures referenced in this disclosure, the dimensions for the various elements are not to scale; some dimensions may be greatly exaggerated vertically and/or horizontally for clarity or emphasis. In addition, references to orientations and directions (e.g., “top”, “bottom”, “above”, “below”, “lateral”, “vertical”, “horizontal”, etc.) are relative to the example drawings, and not necessarily absolute orientations or directions.

Various embodiments of the invention can be implemented to meet a wide variety of specifications. Unless otherwise noted above, selection of suitable component values is a matter of design choice. Various embodiments of the invention may be implemented in any suitable integrated circuit (IC) technology (including but not limited to MOSFET structures), or in hybrid or discrete circuit forms. Integrated circuit embodiments may be fabricated using any suitable substrates and processes, including but not limited to standard bulk silicon, high-resistivity bulk CMOS, silicon-on-insulator (SOI), and silicon-on-sapphire (SOS). Unless otherwise noted above, embodiments of the invention may be implemented in other transistor technologies, such as bipolar junction transistors (BJTs), BiCMOS, LDMOS, BCD, GaAs HBT, GaN HEMT, GaAs pHEMT, MESFET, InP HBT, InP HEMT, FinFET, GAAFET, and SiC-based power device technologies, using 2-D, 2.5-D, and 3-D structures. However, embodiments of the invention are particularly useful when fabricated using an SOI or SOS based process, or when fabricated with processes having similar characteristics. Fabrication in CMOS using SOI or SOS processes enables circuits with low power consumption, the ability to withstand high power signals during operation due to FET stacking, good linearity, and high frequency operation (i.e., radio frequencies up to and exceeding 300 GHz). Monolithic IC implementation is particularly useful since parasitic capacitances generally can be kept low (or at a minimum, kept uniform across all units, permitting them to be compensated) by careful design.

Voltage levels may be adjusted, and/or voltage and/or logic signal polarities reversed, depending on a particular specification and/or implementing technology (e.g., NMOS, PMOS, or CMOS, and enhancement mode or depletion mode transistor devices). Component voltage, current, and power handling capabilities may be adapted as needed, for example, by adjusting device sizes, serially “stacking” components (particularly FETs) to withstand greater voltages, and/or using multiple components in parallel to handle greater currents. Additional circuit components may be added to enhance the capabilities of the disclosed circuits and/or to provide additional functionality without significantly altering the functionality of the disclosed circuits.

### CONCLUSION

A number of embodiments of the invention have been described. It is to be understood that various modifications may be made without departing from the spirit and scope of the invention. For example, some of the steps described above may be order independent, and thus can be performed in an order different from that described. Further, some of the steps described above may be optional. Various activities described with respect to the methods identified above can be executed in repetitive, serial, and/or parallel fashion.

It is to be understood that the foregoing description is intended to illustrate and not to limit the scope of the invention, which is defined by the scope of the following claims, and that other embodiments are within the scope of the claims. In particular, the scope of the invention includes any and all feasible combinations of one or more of the processes, machines, manufactures, or compositions of matter set forth in the claims below. (Note that the parenthetical labels for claim elements are for ease of referring to such elements, and do not in themselves indicate a particular required ordering or enumeration of elements; further, such labels may be reused in dependent claims as references to additional elements without being regarded as starting a conflicting labeling sequence).

1-8. (canceled)

9. A first combinable co-fabricated antenna element, including at least one internally co-fabricated radio frequency antenna element configured to be electrically connectable to a corresponding internally co-fabricated radio frequency antenna element in a second combinable co-fabricated antenna element, wherein the first combinable co-fabricated antenna element and the second combinable co-fabricated antenna element are couplable together by means of 3-D integrated circuit stacking.

10. The invention of claim 9, wherein the first combinable co-fabricated antenna element further includes an active circuitry region.

11. The invention of claim 9, wherein the first combinable co-fabricated antenna element further includes an active circuitry region containing multiple transistors.

12. The invention of claim 9, wherein the at least one internally co-fabricated radio frequency antenna element defines a first plane, and wherein at least one of the first and second combinable co-fabricated antenna elements includes an active circuitry region defining a second plane extending essentially perpendicular to the first plane.

13. A plurality of combinable co-fabricated antenna elements coupled together by means of 3-D integrated circuit stacking, each combinable co-fabricated antenna element including at least one internally co-fabricated radio frequency antenna element configured to be electrically connected to a corresponding radio frequency antenna element in another combinable co-fabricated antenna element.

14. The invention of claim 13, wherein the electrically connected radio frequency antenna elements of the plurality of combinable co-fabricated antenna elements form a grid antenna.

15. The invention of claim 13, wherein at least one of the plurality of combinable co-fabricated antenna elements includes an active circuitry region.

16. The invention of claim 15, wherein the active circuitry region includes an active layer containing multiple transistors.

17. The invention of claim 13, wherein the at least one internally co-fabricated radio frequency antenna element defines a first plane, and wherein at least one of the plurality of combinable co-fabricated antenna elements includes an active circuitry region defining a second plane extending essentially perpendicular to the first plane.

18. The invention of claim 13, wherein at least one of the plurality of combinable co-fabricated antenna elements includes a radio frequency integrated circuit including the at least one internally co-fabricated radio frequency antenna element.

19. The invention of claim 13, wherein at least one of the plurality of combinable co-fabricated antenna elements includes an embedded die package including the at least one internally co-fabricated radio frequency antenna element.

20. A plurality of combinable co-fabricated antenna elements coupled together by means of 3-D integrated circuit stacking, each combinable co-fabricated antenna element including at least one internally co-fabricated radio frequency antenna patch.

21. The invention of claim 20, wherein each combinable co-fabricated antenna element includes a plurality of radio frequency antenna patches.

22. The invention of claim 20, wherein a combination of the radio frequency antenna patches of the plurality of combinable co-fabricated antenna elements forms an antenna array.

23. The invention of claim 20, wherein at least one of the plurality of combinable co-fabricated antenna elements includes an active circuitry region.

24. The invention of claim 23, wherein the active circuitry region includes an active layer containing multiple transistors.

25. The invention of claim 20, wherein the at least one internally co-fabricated radio frequency antenna patch defines a first plane, and wherein at least one of the plurality of combinable co-fabricated antenna elements includes an active circuitry region defining a second plane extending essentially perpendicular to the first plane.

26. The invention of claim 20, wherein at least one of the plurality of combinable co-fabricated antenna elements includes a radio frequency integrated circuit including the at least one internally co-fabricated radio frequency antenna patch.

27. The invention of claim 20, wherein at least one of the plurality of combinable co-fabricated antenna elements includes an embedded die package including the at least one internally co-fabricated radio frequency antenna patch.

28-60. (canceled)
